(19) United States
(12) Patent Application Publication
(10) Pub. No.: US 2006/0088984 A1
(43) Pub. Date: Apr. 27, 2006

(54) Laser ablation method

(75) Inventors: Eric J. Li, Chandler, AZ (US); Christopher L. Rumer, Chandler, AZ (US); Alexander M. Streltsov, Chandler, AZ (US); Mark A. Blocker, Phoenix, AZ (US); Sergei L. Voronov, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 10/972,108

(22) Filed: Oct. 21, 2004

(51) Int. Cl. H01L 21/78; B23K 26/38

(52) U.S. Cl. 438/463; 219/121.61; 219/121.69; 219/121.68

(57) ABSTRACT

A combination of specific laser pulse durations and repetition rates are incorporated into a semiconductor wafer laser scribing/dicing process. The disclosed combination can reduce factors that contribute to thermal effects, explosive melting and evaporation, and laser/plasma interactions, thereby reducing problems with microcracks, delamination, and particles that can affect semiconductor die yields and reliability.

### FIELD OF THE INVENTION

Embodiments of the present invention relate generally to laser micromachining and more specifically to the laser micromachining of semiconductor substrates.

### BACKGROUND OF THE INVENTION

The heat generated during the scribing/dicing of semiconductor wafers can be a concern when using conventional (nanosecond) lasers. Heating can cause problems with microcracking, delamination, and particles, all of which can impact semiconductor die yields and reliability. Heat is generated when optical power from the laser pulse is coupled to the lattice degrees of freedom of the material being lased. When this occurs, high energy electrons (excited by photons from the laser) transfer energy to phonons through electron-phonon interactions. This typically occurs within a matter of tens of picoseconds. As a result, the material heats, melts, and then upon reaching its photo ablation threshold, evaporates.

Due to the thermal nature of nanosecond pulsed laser ablation, the heat produced is not necessarily confined to the area of the laser's focus spot. It can be transferred to other substrate regions via thermal conduction. The heat impacted region is referred to as the heat affected zone. To the extent that heat does not dissipate from the heat affected zone fast enough and optical power continues to be added by the laser pulses, the size of the heat affected zone and thermal effects from heat build-up can increase.

Laser scribing/dicing through multiple layers can compound thermal effects problems. For example, when scribing semiconductor wafers, a stack of multiple metal and dielectric layers must be removed. Since the ablation threshold of metals and wide-bandgap dielectrics such as silicon dioxide is higher than that of other materials (such as for example low-k dielectrics), the fluence (laser energy density) must be increased to accommodate removal of these high ablation threshold materials so that the entire stack can be ablated during a single scribe pass of the laser. As fluence increases so too does the thermal energy delivered to the focus spot and the area of the heat affected zone.

In addition, because of differences in the optical absorption, heat conduction, and thermal properties of individual layers in the stack, some layers will melt and evaporate faster than others, and some layers will expand and contract differently. To the extent that melting and evaporation occurs in an underlying layer, a subsurface boiling phenomenon can occur that rips off upper layers during evaporation. Also, if the stack is heated and coefficients of thermal expansion of layers in the stack do not match, tensile and compressive film stresses can be produced. In either case, microcracking, delamination, and particles can result.

The interaction between the laser pulse and the plasma plume can also create problems during laser scribing/dicing. Optical energy absorbed by the plasma during the laser pulse can reduce the amount of energy delivered to the surface and heat the plume. The heat can cause the plume to expand, whereupon recoiling, mechanical and thermal stresses can be generated. Secondary heating from the expanding plume can also contribute to thermal effects in the heat affected zone. In addition, boiling material caught up in the plasma plume's recoil can recondense and form droplets that contaminate the semiconductor substrate. Also, the reduction in laser energy caused by the laser/plasma interaction results in decreased scribing/dicing efficiency. This problem can be remedied by increasing the fluence. However, increasing fluence compounds problems with thermal effects.

### BRIEF DESCRIPTION OF THE DRAWINGS

FIG. 1 illustrates a portion of a laser pulse train that shows the timing relationship between first and second laser pulses in accordance with an embodiment of the present invention;

FIG. 2 illustrates a top-down view of die formed on a semiconductor substrate;

FIGS. 3 and 4 are expanded views of the die shown in FIG. 2 that illustrate alternative techniques for scribing wafers using embodiments of the present invention;

FIG. 5 is a cross-sectional micrograph of a wafer street region that has been scribed using a conventional nanosecond laser;

FIG. 6 is a cross-sectional micrograph of a wafer street region that has been scribed using an ultrafast laser, wherein the time between laser pulses is less than the plasma lifetime; and

FIG. 7 is a cross-sectional micrograph of a wafer street region that has been scribed using an embodiment of the present invention.

It will be appreciated that for simplicity and clarity of illustration, elements in the drawings have not necessarily been drawn to scale. For example, the dimensions of some of the elements may be exaggerated relative to other elements for clarity. Further, where considered appropriate, reference numerals have been repeated among the drawings to indicate corresponding or analogous elements.

### DETAILED DESCRIPTION

In the following detailed description, a method for laser scribing/dicing semiconductor substrates is disclosed. Reference is made to the accompanying drawings within which are shown, by way of illustration, specific embodiments by which the present invention may be practiced. In other instances, well known features may be omitted or simplified in order not to obscure embodiments of the present invention. It is to be understood that other embodiments may exist and that other structural changes may be made without departing from the scope and spirit of the present invention.

In accordance with an embodiment of the present invention, specific laser pulse durations and repetition rates are incorporated into a laser scribing/dicing process. The disclosed processes can reduce/eliminate factors that contribute to thermal effects, explosive melting and evaporation, and laser/plasma interactions, thereby reducing microcracking, delamination, and particles that can affect semiconductor die yields and reliability.

Although embodiments of the present invention are discussed in reference to the scribing of semiconductor wafers, one of ordinary skill appreciates that the methods disclosed herein are not limited to such applications and that other types of workpieces can be micromachined using embodiments that fall within the scope and spirit of the present invention.

In one embodiment, semiconductor wafer scribe lines (street regions) are scribed/diced by projecting a train of laser pulses onto the wafer. In one embodiment, the duration of each of the laser pulses is less than approximately 100 picoseconds. In one embodiment, the time interval between laser pulses is greater than or equal to the lifetime of the plasma plume produced by the first laser pulse (plasma lifetime is typically on the order of hundreds of nanoseconds depending upon the irradiation conditions, the materials ablated, and the ambient environment). Studies reporting plasma plume lifetimes have been reported by K. H. Song, et al., “Mechanisms of absorption in pulsed excimer laser-induced plasma,” Applied Physics A (Materials Science Processing), vol.65, no.4-5, October 1997. p. 477-85; and R. Stoian et al., “Surface charging and impulsive ion ejection during ultrashort pulsed laser ablation,” Physical Review Letters, vol.88, no.9, Mar. 4, 2002. p. 097603/1-4.

In one embodiment, the time interval between laser pulses in the pulse train is be greater than the time it takes for the work piece to substantially dissipate the heat generated by the laser pulse away from the heat affected zone (heat dissipation time). Generally speaking, the heat dissipation time is believed to be on the order of a microsecond. More specifically, since dielectrics conduct heat slower than metals, their heat diffusivity is believed to more strongly impact heat dissipation times. Therefore, assuming that the heat diffusivity for dielectric materials in the film stack approximates that of silicon (i.e. k=0.8 cm²/s) and that the radius of the laser's irradiated area is approximately 5 microns (um), then the heat dissipation time, as given by the equation t=(4r2)/k, can be calculated to be approximately one microsecond (i.e. t˜1 us).

In an exemplary embodiment, where the plasma lifetime and heat dissipation times are less than approximately one microsecond, the time period between the first pulse and the second pulse should be greater than approximately one microsecond. In other words, under circumstances where (1) the lifetime of the plasma produced by a laser pulse, and (2) the time it takes to substantially dissipate heat produced by the laser pulse away from the heat affected zone is less than approximately one microsecond, thermal damage can be reduced (as compared to prior art methods) by adjusting the repetition rate of the laser pulses to be equal to or less than approximately one megahertz. One of ordinary skill appreciates that the plasma lifetime, the heat dissipation time or both should be considered when determining the optimal timing between laser pulses. Therefore, to the extent that either of these is greater than or less than the one microsecond, then the time between laser pulses can correspondingly be greater than or less than one microsecond.

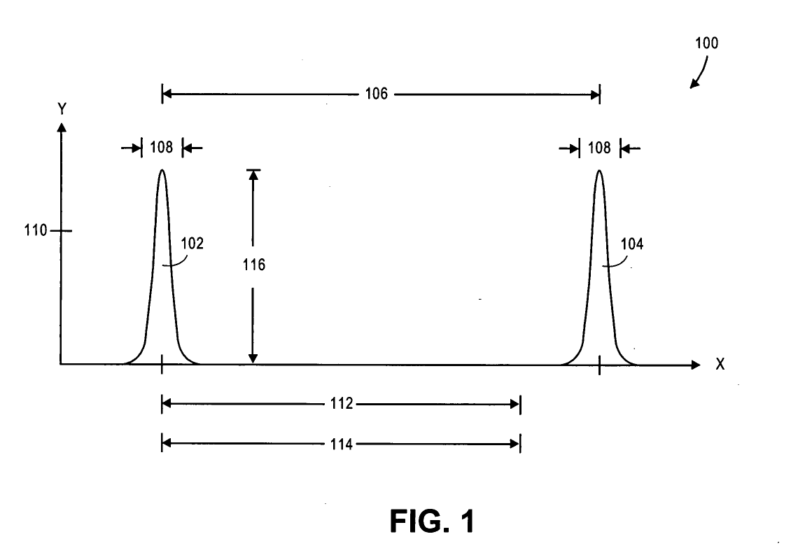

FIG. 1 illustrates the intensity, duration, and repetition rate of laser pulses in accordance with a preferred embodiment of the present invention. Shown in FIG. 1 are two laser pulses 102 and 104 that are representative of the timing relationship of a series of pulses (pulse train) used to ablate a workpiece, such as a semiconductor wafer. As shown in FIG. 1, a first laser pulse 102 is followed by a second laser pulse 104. In one embodiment, the laser source is a neodymium: yttrium aluminum garnet (Nd:YAG)laser that projects coherent radiation having a wavelength in the near infrared (IR) wavelength regime (i.e., wavelength is between 800 nanometers (nm) and two microns (um)).

In a preferred embodiment, the laser pulse intensity 116 is greater than the photo-ablation threshold 110 of each material in the stack being lased, the laser's wavelength is one micron or longer, and the pulse duration is less than the electron-phonon interaction time scale. A pulse intensity 116 that is greater than the ablation threshold of each material in the film stack is preferred to insure that all wafer street material will be removed. Wavelengths of one micron or longer are preferred because at these wavelengths the ablation threshold is less sensitive to the absorption spectrum of the material being lased and material removal can occur in the non-linear absorption and non-thermal ablation regimes. Pulse durations that are less than the electron-phonon interaction time scale are preferred because this can reduce energy transferred into the lattice.

In one embodiment, the pulse duration 108, is less than approximately 100 picoseconds. Preferably the pulse duration 108 is less than approximately 10 picoseconds. And more preferably, the pulse duration is less than approximately one picosecond (1000 femtoseconds). Decreasing the laser pulse duration to a time period that is substantially less than the time it takes for the energy to transfer to the atom's lattice system inhibits the direct coupling of the laser's radiation to the sample's lattice phonons. This significantly reduces the generation of heat. At these pulse durations, ablation is not accomplished by the melting/evaporation that results from the laser's energy being transferred to the atom's lattice system. Instead, the atoms are ionized directly by single or multi-photon absorption before energy transfer from the electronic system to the lattice system can occur. This results in ultrafast bond scission and effective material removal via sublimation. Little or no thermal and mechanical stress is generated and damage, cracking, and delamination in areas surrounding the lased area are significantly reduced.

As shown in FIG. 1, the interval 106 between laser pulses 102 and 104 is greater than the lifetime of the plasma 112 generated by the laser pulse 102. By increasing the interval between the laser pulses 102 and 104 in the train until after the plasma has substantially decayed, interaction problems between the plasma and the second laser pulse is reduced/eliminated. Therefore, no increase must be made to the optical energy delivered to the material's surface to compensate for the reduction in delivered optical power that can result from the interaction. As a result, scribing efficiency is increased. Also, because the laser pulsing is timed so as not to be concurrent with the existence of the plasma, plasma heating caused by the laser is reduced/eliminated.

In addition, as also shown in FIG. 1, the interval 106 between pulses 102 and 104 is greater than the heat dissipation time 114. Typically this time is believed to be less than approximately 1 microsecond. By staging laser pulses to occur after heat generated from the prior pulse has dissipated, problems with heat build-up can be reduced.

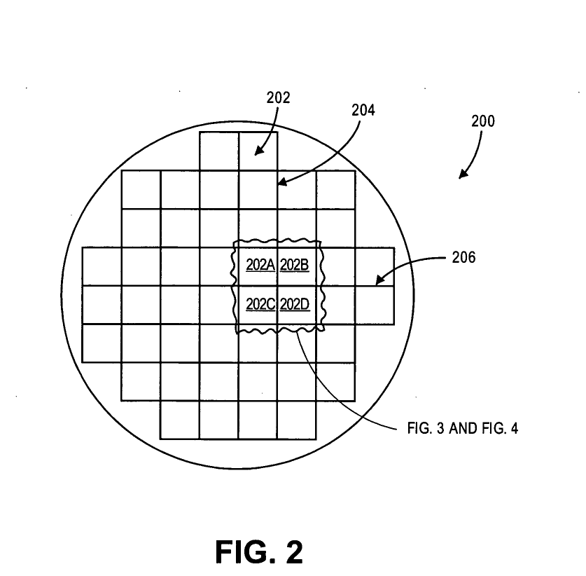

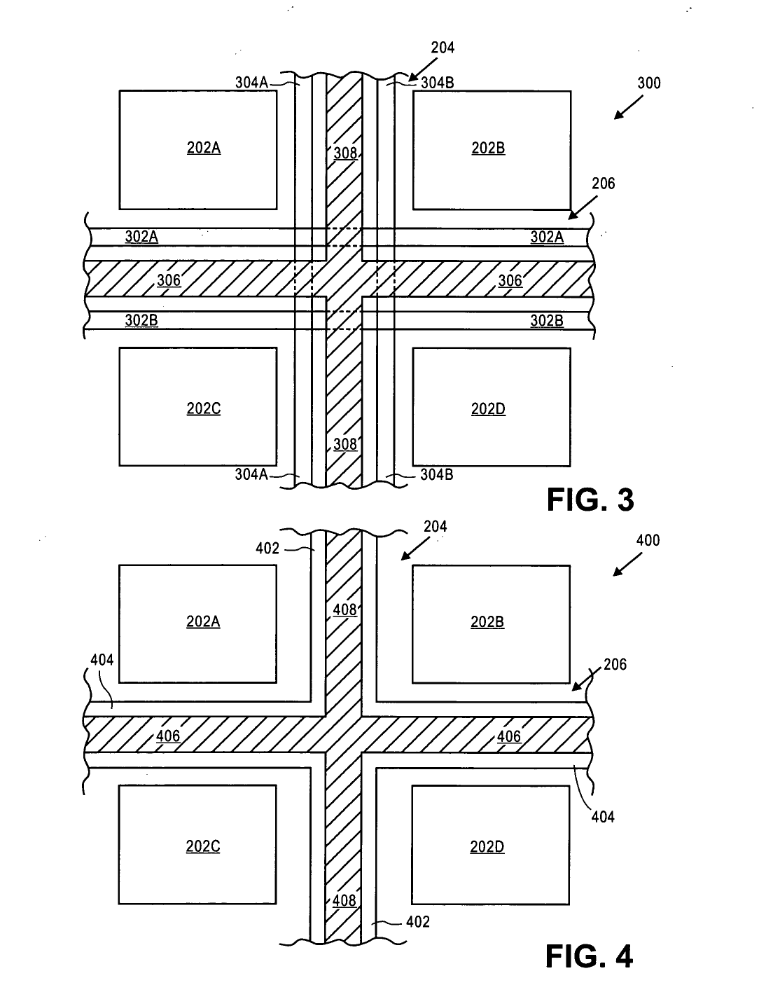

FIGS. 2-4 describe generally, methods for scribing semiconductor wafers using a laser system that incorporates one or more embodiments of the present invention. Turning now to FIG. 2, a top-down view of semiconductor wafer 200 that includes semiconductor die 202 is shown. The semiconductor die 202 can include circuitry that forms an integrated circuit device, such as a microprocessor, a chipset device, a memory device, or the like. At the intersection of street regions 204 and 206 are dice 202A, 202B, 202C, and 202D. Expanded views of the dice 202A, 202B, 202C, and 202D are shown in FIGS. 3 and 4. FIGS. 3 and 4 will be used to describe the scribing of wafers using a laser that incorporates one or more embodiments of the present invention.

Turning now to FIG. 3, a first method for laser scribing is shown, wherein laser kerfs 302A, 302B, and 304A, 304B are formed toward edges of street region 206 and 204, respectively. The laser kerfs are formed by removing street region material using a laser ablation process that incorporates one or more embodiments of the present invention. The street region can include dielectric materials such as low-k dielectrics, silicon nitrides, silicon carbides, silicon dioxide, or the like; conductive materials that include copper, aluminum, refractory metals, or the like; and semiconductor materials, such as crystalline silicon, polysilicon, amorphous silicon, or the like. A train of pulses from the laser is focused onto the street region, whereby material in the streets is removed and the laser kerf regions are formed. The laser kerf regions stop in or on the underlying silicon substrate. Next a wafer dicing saw is used to cut saw kerfs 306 and 308 through the center of the streets 206 and 204, as shown in FIG. 3. The saw removes dielectric, conductive, semiconductive, and substrate material and thereby singulates the wafer. In this embodiment, the laser kerf functions as a crack arrestor, thereby preventing the propagation of cracks that are formed by the saw from extending into the integrated circuit.

An alternative scribing method is disclosed in FIG. 4, whereby laser kerfs 402 and 404 are formed in the center of street regions 204 and 206 respectively. In this embodiment, the laser kerfs are formed to be wider than the wafer dicing saw blade and they extend through the layers of street region material (i.e. dielectric, conductive, and semiconductive material) down to the substrate. Following the laser scribe to form the kerfs 402 and 404, the saw is used to cut through the substrate exposed by the laser and thereby singulate the wafer. Here, since the saw contacts only the substrate (i.e. it does not contact any layers of street region material) no thermal or mechanical stresses are generated in the films formed over the semiconductor substrate. This technique may be advantageous in that the saw blade does not have to remove the dielectric and metal material in the street region. This reduces blade loading and can extend the life and reliability of the blade and the overall cost of the sawing process.

By using embodiments of the present invention, the complex interactions among the electronic system, the lattice, heat-diffusion, and the plasma can be decoupled or eliminated. Reducing the pulse duration into the picosecond or femtosecond time regimes reduces/eliminates energy transfer from the electrons system to the phonon system. This reduces heating, and consequently melting and surface/subsurface boiling, all of which can contribute to particles, cracking, and delamination. Separating the time between laser pulses to permit adequate diffusion of heat that is generated by a laser pulse reduces the build-up of the heat and the size of the heat affected zone. Separating the laser pulses by at least the time it takes for the plasma plume to decay prevents plasma interference with the laser's operation. Thus, laser fluence adjustments that may have been necessary to compensate for this interference are minimized or eliminated. Also, now there is no secondary heating which results from interactions between the laser pulse and the plasma due to their occurrence in different time domains. In addition, the laser scribing/dicing processes disclosed herein produce debris that is smaller than that generated by conventional nanosecond thermal ablation methods. Here, materials are processed via a relatively cold ablation “atomization” process. The atoms are ionized directly by breaking atomic bonds to remove material, thereby producing of mono-atomic clusters of the removed material. This is in contrast to the localized intense heating, melting, and boiling of material associated with longer pulse width (i.e., nanosecond) lasers. In addition, since less heat is generated, the debris is formed at a cooler temperature than with conventional processes. These particles have less tendency to stick to surrounding areas after they are formed, and they can be easily removed using air instead of with wet processing, which correspondingly reduces costs and increases throughput.

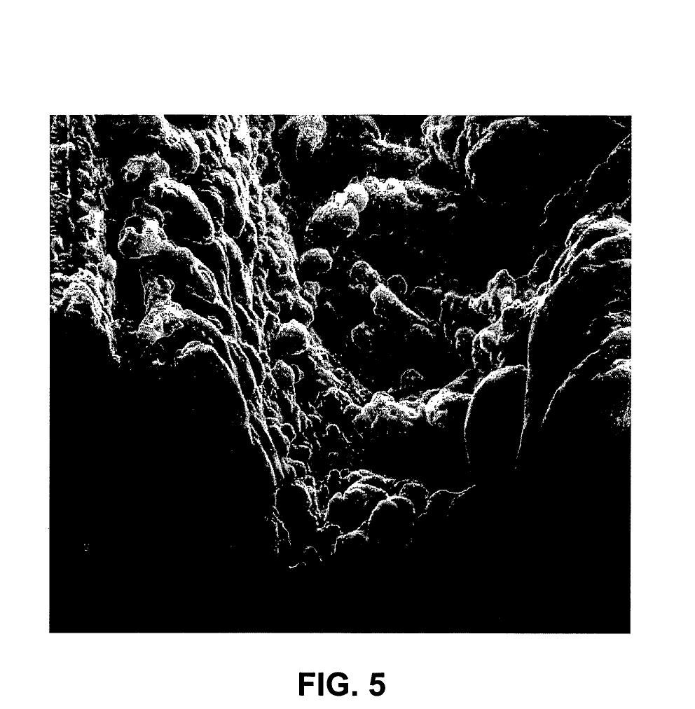

Benefits of using laser scribing processes that practice embodiments of the present invention can better be understood by comparing their effects with laser scribing processes that do not. FIG. 5 is a cross-sectional micrograph of a wafer street region that has been scribed using a conventional nanosecond laser. The physical effects of heating and melting are readily observed. Portions of the street region have been removed by the laser. However, a significant amount of unevaporated material and debris still remains. The irregular nature of the remaining melted and recondensed material is evidence of the physical and thermal nature of the nanosecond laser process.

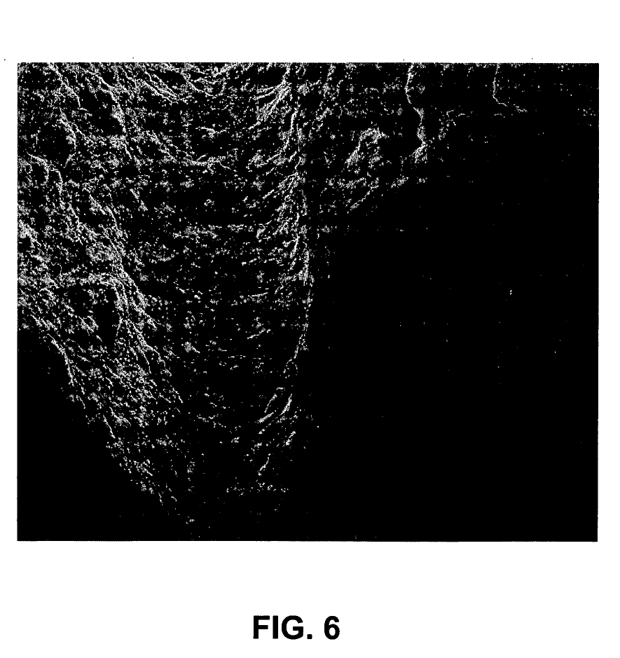

FIG. 6 is a cross-sectional micrograph of a wafer street region that has been scribed using an ultrafast (i.e., picosecond) laser, wherein the time between laser pulses is less than the plasma lifetime and the heat dissipation time. As can be seen in this micrograph, the physical effects of this laser process are less than the case of the nanosecond laser in FIG. 5. However, the secondary heating effects (i.e. heat produced by the combination of the interaction between the incoming laser pulse and the plasma plume and/or not allowing heat generated by the laser pulse to dissipate) has generated significant melting of the street region material. This material has redeposited itself along sidewalls and surface regions of the adjacent semiconductor dice.

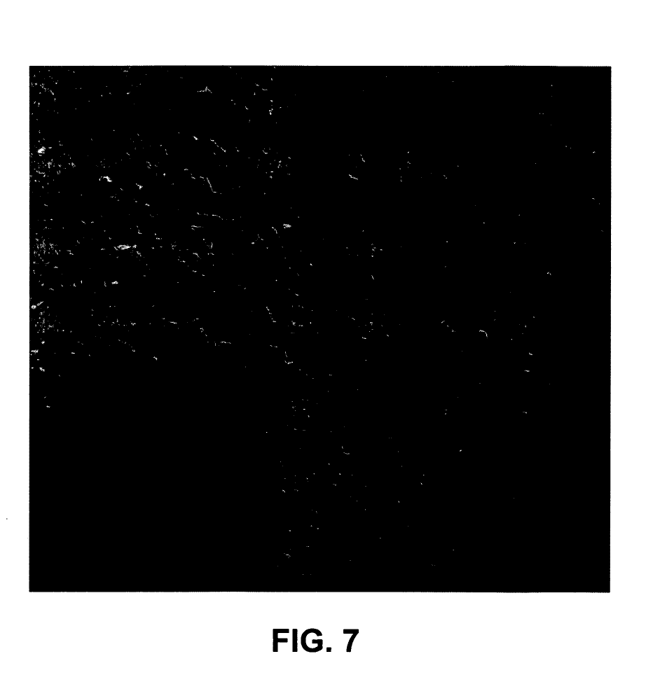

FIG. 7 is a cross-sectional micrograph of a wafer street region that has been scribed using an embodiment of the present invention, wherein the time between laser pulses is greater than the plasma lifetime and the heat dissipation time (i.e., one microsecond). As can be observed in the micrograph of FIG. 7, both the physical and thermal effects have been significantly reduced as compared to the cross-section micrographs shown in FIGS. 5 and 6. Here, because the interactions between the lattice, heat-diffusion, and the plasma have largely been decoupled, the physical effects due to heating, melting, and surface/subsurface boiling have been reduced, and the thermal effects due to secondary heating have also been reduced. There is minimal evidence of damage and unremoved material in the street region and there is minimal build-up of melted lased material on the sidewalls of the wafer dice. Also, the debris that is present in the street region and on the surface of the dice is not typical of the debris produced by the melting and recondensation observed in FIGS. 5 and 6. Consequently, it is much more easily removed.

The various implementations described above have been presented by way of example only and not limitation. Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method for laser micromachining a workpiece comprising:
projecting a laser-pulse train onto the workpiece; and
ablating portions of the workpiece, wherein a time interval between laser pulses in the laser-pulse train is greater than a heat dissipation time of workpiece regions heated by individual laser pulses.

2. The method of claim 1 wherein the time interval between the laser pulses is greater than a lifetime of a plasma produced at the surface of the workpiece by individual laser pulses.

3. The method of claim 1, wherein the laser pulses have pulse durations that are less than 100 picoseconds.

4. The method of claim 1, wherein the laser pulses have pulse durations that are less than 1000 femtoseconds.

5. The method of claim 1, wherein a repetition rate of the laser-pulse train is less than approximately one megahertz.

6. The method of claim 1, wherein the time interval between laser pulses is greater than one microsecond.

7. The method of claim 1, wherein potions of the workpiece is further characterized as semiconductor wafer street regions.

8. The method of claim 7, wherein ablating portions of the workpiece scribes street regions.

9. The method of claim 7, wherein ablating portions of the workpiece dices street regions.

10. A method for forming a semiconductor device comprising:
removing portions of a semiconductor substrate using a series of laser pulses, wherein:
a duration of each of the laser pulses is less than an electron-phonon interaction time; and
a time between a first laser pulse and a second laser pulse in the series of laser pulses is greater than a heat dissipation time of the first laser pulse.

11. The method of claim 10, wherein the time between the first laser pulse and a second laser pulse is greater than a lifetime of a plasma created by the first laser pulse.

12. The method of claim 10, wherein the first and second laser pulses each have a pulse duration that is less than 1000 femtoseconds.

13. The method of claim 10, wherein the first and second laser pulses each have a pulse duration that is less than 10 picoseconds.

14. The method of claim 10, wherein the first and second laser pulses each have a pulse duration that is less than 100 picoseconds.

15. The method of claim 10, wherein a repetition rate of the series of laser pulses is less than approximately one megahertz.

16. The method of claim 15, wherein removing portions of the semiconductor substrate scribes the semiconductor substrate.

17. The method of claim 15, wherein removing portions of the semiconductor substrate dices the semiconductor substrate.

18. A semiconductor dice having regions that have been removed by a series of laser pulses, wherein a duration of each of the laser pulses is less than approximately 100 picosecond and a time between a first laser pulse and a second laser pulse in the series of laser pulses is greater than a heat dissipation time of the first laser pulse.

19. The semiconductor dice of claim 18, wherein the time between the first laser pulse and a second laser pulse in the series of laser pulses is greater than a lifetime of a plasma created by the first laser pulse.

20. The semiconductor dice of claim 18, wherein the first laser pulse and the second laser pulse each have a pulse duration that is less than 1000 femtoseconds.

21. The semiconductor dice of claim 18, wherein a repetition rate of the series of laser pulses is less than approximately one megahertz.

22. The semiconductor dice of claim 18, wherein the regions removed by the series of laser pulses are further characterized as street regions of a semiconductor substrate.

23. A semiconductor device that has been singulated from a semiconductor wafer by projecting a laser-pulse train onto the semiconductor wafer, wherein a time interval between laser pulses in the laser-pulse train is greater than a heat dissipation time of regions in the semiconductor wafer that are heated by individual laser pulses.

24. The semiconductor device of claim 23, wherein the time interval between the laser pulses is greater than a lifetime of a plasma produced at the surface of the semiconductor wafer by individual laser pulses.

25. The semiconductor device of claim 23, wherein each of the laser pulses have a duration that is less than 100 picoseconds.

26. The semiconductor device of claim 23, wherein the each of the laser pulses have a duration that is less than 1000 femtoseconds.

27. The semiconductor device of claim 23, wherein a repetition rate of the laser-pulse train is less than approximately one megahertz.

28. The semiconductor device of claim 23, wherein the time interval between laser pulses is greater than one microsecond.

29. The semiconductor device of claim 23, wherein projecting a laser-pulse train onto the semiconductor wafer scribes street regions of the semiconductor wafer.
